(19) United States
(12) Patent Application Publication
(10) Pub. No.: US 2007/0015088 A1
(43) Pub. Date: Jan. 18, 2007

(54) METHOD FOR LITHOGRAPHICALLY PRINTING TIGHTLY NESTED AND ISOLATED HOLE FEATURES USING DOUBLE EXPOSURE

(76) Inventor: Chin-Lung Lin, Hsin-Chu Hsien (TW)

Correspondence Address: NORTH AMERICA INTELLECTUAL PROPERTY CORPORATION, P.O. BOX 506, MERRIFIELD, VA, 22116, US

(21) Appl. No.: 11/160,923

(22) Filed: Jul. 15, 2005

(51) Int. Cl. G03C 5/00; G03F 1/00

(52) U.S. Cl. 430/311; 430/5; 430/312; 430/313

(57) ABSTRACT

A mask pattern including a group of small-pitched contact hole features with pitch being less than a predetermined value and isolated contact hole features with pitch being greater than the predetermined value is provided. The mask pattern is split into two sub-mask patterns, one having about half of the group of the small-pitched contact hole features and about half of the isolated contact hole features, the other having the rest of the group of the small-pitched contact hole features and the rest of the isolated contact hole features. Two phase shifting masks are formed, each phase shifting mask comprising one of the two sub-mask patterns and dummy features disposed in proximity to each of the contact hole features. Successively, each of the two phase shifting masks is positioned above the substrate. Each phase shifting mask is exposed successively on a photosensitive layer on the substrate.

### BACKGROUND OF THE INVENTION

1. Field of the Invention

The present invention relates generally to the field of semiconductor device manufacturing and, more specifically, to a dual-mask/double-exposure method for lithographically printing tightly nested hole features and isolated hole features in integrated circuits with substantially the same exposure energy.

2. Description of the Prior Art

Lithography technology is arguably the most important and essential part in the fabrication of ULSI devices. Continued improvements in optical projection lithography have enabled the printing of ever-finer features of integrated circuits. This, in turn, has allowed the integrated circuit industry to produce ever more powerful and cost-effective semiconductor devices.

In the field of optical lithographic processing, a photosensitive material is applied to a silicon substrate wafer and then allowed to dry. An exposure tool is utilized to expose the wafer with proper geometrical patterns through a mask by means of a source of light or radiation. After exposure, the wafer is treated to develop the mask images transferred to the photosensitive material. These masking patterns are then used to create the device features of the circuit.

The wavelength used in exposure has been reduced to make finer patterns. However, the rate of shrinkage in device pattern is so fast that it has become difficult to achieve enough resolution only by reduction of exposure wavelength. Several resolution enhancement technologies such as optical proximity correction and phase shifting techniques have been developed to cope with these problems.

As critical dimension of circuit shrinks to 100-nanometer node or below, the photolithographic printing of via/hole patterns becomes much more and more critical. U.S. Pat. No. 6,541,166 to Mansfield et al. discloses a method of lithographically printing contact hole patterns on a substrate. The pattern includes contact hole features with diverse pitches. First, the contact hole features are grouped into two feature groups according to pitch. The two feature groups includes a dense hole group wherein the pitch is less than a predetermined value and an isolated hole group wherein the pitch is greater than the predetermined value. Subsequently, two sub-masks are formed. One of the two sub-masks includes the dense hole group and the other sub-mask includes the isolated hole group. Using the two sub-masks and double exposure, the dense hole and the isolated hole features are succeedingly printed on a photoresist layer on a substrate.

The main drawback of the above-described prior art patent is that the magnitudes of the exposure energy of light required in each exposure of the double exposure procedure are not the same since the original contact hole features are divided into a relatively denser hole group and a relatively isolated hole group according to a predetermined pitch value. Careful adjustment of the imaging parameters of the stepper prior art to each successive exposure is required. This retards the throughput and might compromise the yield.

### SUMMARY OF THE INVENTION

It is the primary object of the present invention to provide an improved method for lithographically printing tightly nested and isolated hole features using double exposure with the same exposure energy in order to solve the above-mentioned prior art problem.

According to the claimed invention, a method of lithographically printing a mask pattern on a substrate is disclosed. A mask pattern including a group of small-pitched contact hole features with pitch being less than a predetermined value and isolated contact hole features with pitch being greater than the predetermined value is provided. The mask pattern is split into two sub-mask patterns, one having about half of the group of the small-pitched contact hole features and about half of the isolated contact hole features, the other having the rest of the group of the small-pitched contact hole features and the rest of the isolated contact hole features. Two phase shifting masks are formed, each phase shifting mask comprising one of the two sub-mask patterns and dummy features disposed in proximity to each of the contact hole features. A photosensitive layer is coated on the substrate. Successively, each of the two phase-shifting masks is positioned above the substrate. Each of the two phase-shifting masks is exposed successively on the photosensitive layer with substantially the same exposure energy.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1 is a schematic plan view of two sub-mask patterns split from a mask pattern having a group of tightly nested contact hole features in accordance with one preferred embodiment this invention; and

FIG. 2 is a schematic plan view of two sub-mask patterns split from a mask pattern having a tightly nested contact hole features and isolated contact hole features in accordance with another preferred embodiment this invention.

### DETAILED DESCRIPTION

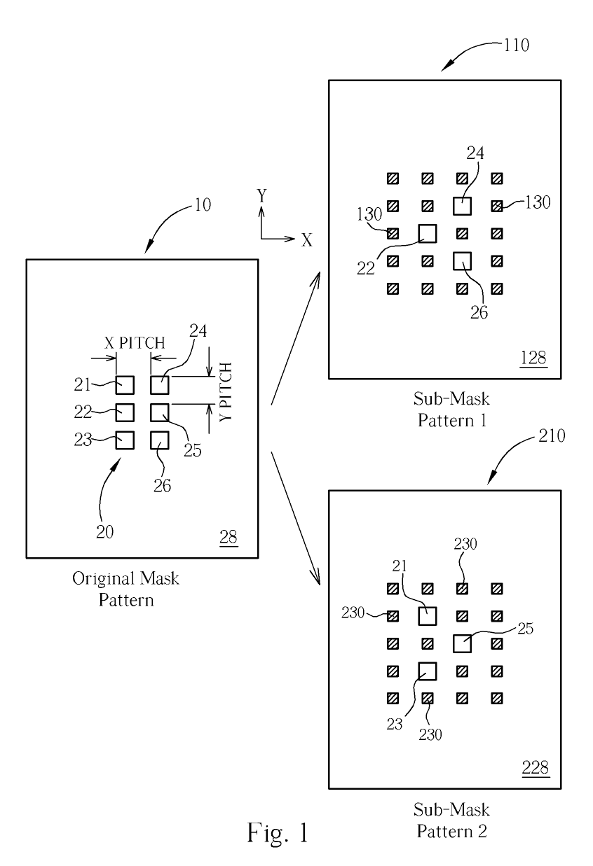

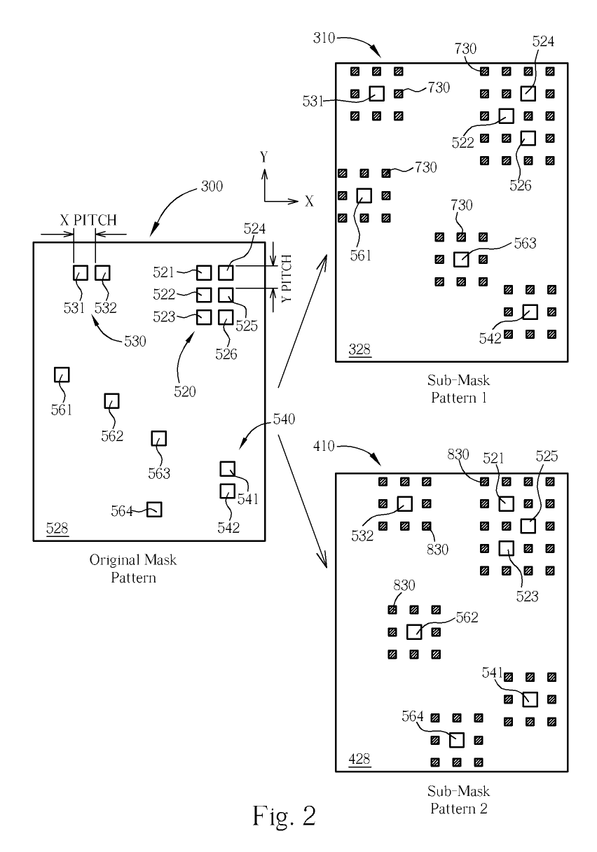

In describing the preferred embodiment of the present invention, reference will be made herein to FIGS. 1-2 of the drawings, wherein like numerals designate like components, areas or regions. Features of the invention are not drawn to scale in the drawings.

Hereinafter, the term “exposure” is defined as the process of subjecting a resist to light energy for the purpose of causing chemical change in the resist. The term “exposure energy” is defined as the amount of energy per unit area that the resist is subjected to upon exposure by a lithographic exposure system. For optical lithography it is equal to the light intensity times the exposure time. Accurate control of the exposure energy delivered to the resist is an important function of a lithographic exposure tool. It is often desirable to employ the same exposure energy in the double exposure.

FIG. 1 shows the concept of this invention. As shown in FIG. 1, mask pattern 10 contains a group of tightly nested contact hole features 20 represented by a plurality of small pitched, light-penetrating bright areas 21-26 for transmitting illumination light, and a masking dark area 28 for blocking illumination light. Light-penetrating bright areas 21-26 represent small contact hole features or vias to be lithographically printed on a semiconductor substrate. The contact hole features 21-26 are located in close proximity to neighboring contact hole features and therefore have a relatively tight pitch either in X direction (reference X-axis) or Y direction (reference Y-axis).

According to one preferred embodiment, the contact hole feature size for each of contact hole features 21-26 is less than 0.2 micrometers. The space between the light-penetrating bright areas 21-26 is equal to the critical dimension (CD) or minimum line width of the circuit to be formed on the semiconductor substrate. According to one preferred embodiment, the space between the contact hole features 21-26 is less than 0.2 micrometers. The pitch of the tightly nested contact hole features 20 in X direction (denoted as X pitch) is less than 0.4 micrometers. The pitch of the tightly nested contact hole features in Y direction (denoted as Y pitch) is less than 0.4 micrometers.

It is known that the feature size on the mask often differs from the feature size to be printed on the wafer stack. If it is desired to print a contact hole pattern at a dimension larger than its mask dimension, the radiation dose is increased to an “over-exposure” condition. Similarly, if it is desired to print a contact hole pattern at a dimension smaller than its mask dimension, the dose is decreased to an “under-exposure” condition. The difference between the dimension printed on the wafer stack and the mask dimension is called the “mask bias.” In addition, the stepper magnification is typically 4×. However, in the following discussion, the mask bias is zero and the stepper magnification is 1× for purposes of illustrating the present invention.

In FIG. 1, the mask pattern 10 is split into two sub-mask patterns 110 and 210. The sub-mask pattern 110 has the light-penetrating bright areas 22, 24 and 26 of the original six light-penetrating bright areas 21-26 of the mask pattern 10. The sub-mask pattern 210 has the light-penetrating bright areas 21, 23 and 25 of the original six light-penetrating bright areas 21-26 of the mask pattern 10. It is one main feature of the present invention that the originally small pitched, light-penetrating bright areas 21-26 of the mask pattern 10 is split into two sub-mask patterns 1110 and 210 which are both relatively more isolated and having substantially the same pattern density.

According to the preferred embodiment, the two sub-mask patterns 110 and 210 are both phase shifting masks. A plurality of dummy features 130 are added in proximity to the light-penetrating bright areas 22, 24 and 26 of the sub-mask pattern 110. The remaining area of the sub-mask pattern 110 is opaque area 128. A plurality of dummy features 230 are added in proximity to the light-penetrating bright areas 21, 23 and 25 of the sub-mask pattern 210. The remaining area of the sub-mask pattern 210 is opaque area 228. The dummy features 130 and 230, which have dimensions less than the resolution of the exposure tool, have the same transparency as the light-penetrating bright areas 21-26 but are 180-degree phase different from the light-penetrating bright areas 21-26.

The two sub-mask patterns 110 and 210 can then be used in two photolithography printing steps. In the first step, sub-mask pattern 110 is used to print the contact hole features 22, 24 and 26 in a photolithography process having predetermined imaging parameters including exposure energy optimized for this relatively looser pitch. In the second photolithography step, sub-mask pattern 210 is used to print the contact hole features 21, 23 and 25 with imaging parameters substantially the same as those employed in the first step. The order of these two printing steps is not critical.

Please refer to FIG. 2. FIG. 2 is a schematic plan view of two sub-mask patterns split from a mask pattern having a tightly nested contact hole features and isolated contact hole features in accordance with another preferred embodiment this invention. As shown in FIG. 2, mask pattern 300 contains a group of tightly nested contact hole features 520 represented by light-penetrating bright areas 521-526 which are analogous to the light-penetrating bright areas 21-26 of FIG. 1, a group of tightly pitched contact hole features 530 represented by light-penetrating bright areas 531-532 at the upper left hand side corner of the mask pattern 300, a group of tightly pitched contact hole features 540 represented by light-penetrating bright areas 541-542 at the lower right hand side corner of the mask pattern 300, isolated contact hole features 561-564, and a masking dark area 528 for blocking illumination light.

Light-penetrating bright areas 521-526, 531-532, 541-542, and 561-564 represent small contact hole features or vias to be lithographically printed on a semiconductor substrate. The contact hole features 521-526 are located in close proximity to neighboring contact hole features and therefore have a relatively tight pitch either in X direction (reference X-axis) or Y direction (reference Y-axis). For example, the X or Y pitch of the tightly nested contact hole features 520 is less than 0.4 micrometers. The contact hole features 531-532 are located in close proximity to each other and have a relatively tight pitch in X direction. The X pitch of the group of contact hole features 530 is less than 0.4 micrometers. The contact hole features 541-542 are located in close proximity to each other and have a relatively tight pitch in Y direction. The Y pitch of the group of contact hole features 540 is less than 0.4 micrometers. Contact hole features 561-564 are located further apart and therefore are relatively isolated. The pitch of contact hole features 561-564 is greater than or equal to about 450 nm.

The mask pattern 300 is split into two sub-mask patterns 310 and 410. The sub-mask pattern 310 has the light-penetrating bright areas 522, 524 and 526 of the contact hole feature group 520, the light-penetrating bright area 531 of the contact hole feature group 530, the light-penetrating bright area 542 of the contact hole feature group 540, and the light-penetrating bright areas 562 and 564. The sub-mask pattern 410 has the light-penetrating bright areas 521, 523 and 525 of the contact hole feature group 520, the light-penetrating bright area 532 of the contact hole feature group 530, the light-penetrating bright area 541 of the contact hole feature group 540, and the light-penetrating bright areas 561 and 563. The two sub-mask patterns 310 and 410 are both relatively more isolated than the mask pattern 300 and have substantially the same pattern density.

The two sub-mask patterns 310 and 410 are both phase shifting masks. A plurality of dummy features 730 are added in proximity to the light-penetrating bright areas of the sub-mask pattern 310. The remaining area of the sub-mask pattern 310 is opaque area 328. A plurality of dummy features 830 are added in proximity to the light-penetrating bright areas of the sub-mask pattern 410. The remaining area of the sub-mask pattern 410 is opaque area 428. The dummy features 730 and 830, which have dimensions less than the resolution of the exposure tool, are 180-degree phase different from the light-penetrating bright areas.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of lithographically printing a mask pattern on a substrate, the method comprising:
providing a mask pattern including at least a group of small-pitched contact hole features with pitch being less than a predetermined value and isolated contact hole features with pitch being greater than the predetermined value;
splitting the mask pattern into two sub-mask patterns, one having about half of the group of the small-pitched contact hole features and about half of the isolated contact hole features, the other having the rest of the group of the small-pitched contact hole features and the rest of the isolated contact hole features;
forming two phase shifting masks, each phase shifting mask comprising one of the two sub-mask patterns and dummy features disposed in proximity to each of the contact hole features;
coating a photosensitive layer on the substrate;
successively positioning each of the two phase shifting masks above the substrate; and
successively exposing each of the two phase shifting masks on the photosensitive layer with substantially the same exposure energy.

2. The method of claim 1 wherein the predetermined value is about 0.4 micrometers.

3. The method of claim 1 wherein the dummy features have dimensions less than the resolution of an exposure tool used to expose each of the two phase shifting masks on the photosensitive layer.

4. The method of claim 1 wherein the dummy features are 180-degree phase different from the contact hole features.

5. The method of claim 1 wherein both of the two sub-mask patterns are relatively more isolated than the mask pattern.

6. A method of lithographically printing a pattern on a substrate, the method comprising:
providing a mask pattern including a group of small-pitched contact hole features with pitch being less than a predetermined value;
splitting the mask pattern into two sub-mask patterns, one having about half of the group of the small-pitched contact hole features, the other having the rest of the group of the small-pitched contact hole features;
forming two phase shifting masks, each phase shifting mask comprising one of the two sub-mask patterns and dummy features disposed in proximity to each of the contact hole features;
coating a photosensitive layer on the substrate;
successively positioning each of the two phase shifting masks above the substrate; and
successively exposing each of the two phase shifting masks on the photosensitive layer with substantially the same exposure energy.

7. The method of claim 6 wherein the predetermined value is about 0.4 micrometers.

8. The method of claim 6 wherein the dummy features have dimensions less than the resolution of an exposure tool used to expose each of the two phase shifting masks on the photosensitive layer.

9. The method of claim 6 wherein the dummy features are 180-degree phase different from the contact hole features.

10. The method of claim 6 wherein both of the two sub-mask patterns are relatively more isolated than the mask pattern.
